(19) United States
(12) Patent Application Publication
(10) Pub. No.: US 2005/0126427 A1
(43) Pub. Date: Jun. 16, 2005

(54) Polymer derivatives for treating metals

(76) Inventors: Monica Fernandez Gonzalez, Heidelberg (DE); Hans-Ulrich Jager, Neustadt (DE); Peter Neumann, Mannheim (DE); Helmut Witteler, Wachenheim (DE)

Correspondence Address: NOVAK DRUCE DELUCA & QUIGG, LLP, 1300 EYE STREET NW, SUITE 400 EAST, WASHINGTON, DC, 20036, US

(21) Appl. No.: 10/500,313

(22) PCT Filed: Dec. 27, 2002
(86) PCT No.: PCT/EP02/14786

(30) Foreign Application Priority Data
Dec. 27, 2001 (EP) 101 64 671.2

(51) Int. Cl. C09D 5/00; C23C 16/00

(52) U.S. Cl. 106/1.16; 427/435; 106/1.25

(57) ABSTRACT

The invention relates to a composition for the treatment of metal surfaces and to the deposition of metals or metal alloys on plastics surfaces, comprising a) at least one polymer as component A, composed of an amino-containing polymer (component Aa), at least one aromatic compound (component Ab), and, where appropriate, an aldehyde (component Ac); b) water or another solvent suitable for dissolving, dispersing, suspending or emulsifying the polymer, as component B; c) if desired, surface-active compounds, dispersants, suspension media and/or emulsifiers as component C. The invention further relates to a process for the treatment of a metal surface and also to a process for the deposition of metals or metal alloys on a-plastics surface in which the metal or plastics surface is contacted with a polymer (component A). The invention further relates to the use of polymers (component A) for the treatment of metal surfaces and for the deposition of metals or metal alloys on a plastics surface, and to polymers composed of specific components A′a, Ab and A′c.

The invention relates to compositions for treating metal surfaces, to processes for treating metal surfaces for corrosion protection, to the use of polymers for treating metal surfaces, and to polymers suitable for treating metal surfaces. The invention further relates to a composition and a process for depositing metals or metal alloys on plastics surfaces.

Metal corrosion poses a problem in the production, processing, and use of articles comprising metals. In order to retard or prevent the corrosion, therefore, protective films and corrosion inhibitors are used. Whereas a protective film is applied permanently to the metal, a corrosion inhibitor is preferably added to substances, especially liquid mixtures, which would cause or accelerate corrosion were they to come into contact with the metal. Both the protective, films and the corrosion inhibitors may comprise, or be present in the form of, polymers. Particular interest attaches to compositions in-which there is no need to use any toxic chromate. Such compositions are already known from the prior art.

U.S. Pat. No. 4,992,116 describes aqueous, chromium-free compositions and a process for treating aluminum. These compositions comprise phosphate ions and a compound containing an element from the group consisting of Zr, Ti, Hf and Si and based on fluorozirconic, fluorotitanic, fluorohafnic, and fluorosilicic acid. The compositions further comprise a polyphenol obtained by Mannich reaction of an amine with a compound selected from the group consisting of polyalkenylphenols and tannins. According to U.S. Pat. No. 4,992,116, aluminum surfaces treated with said compositions match chromium-based compositions for adhesion and corrosion resistance.

WO 92/07973 relates to chromium-free corrosion protectants for treating aluminum or aluminum alloys, which comprise a water-soluble or water-dispersible polymer. The compositions of WO 92/07973 comprise an acidic aqueous solution which, in addition to water, comprises fluorozirconic acid, dispersed SiO2 if desired, a nonaqueous solvent, a surfactant, and 3-(N-C₁₋₄ alkyl-N-2-hydroxyethylaminomethyl)-4-hydroxystyrene. According to WO 92/07973, these specific compositions are particularly suitable for treating aluminum surfaces.

DE-A 100 10 758 relates to a process for corrosion-protective treatment of vehicle bodies or domestic appliances that have at least in part a metallic surface composed to the extent of at least 90% of zinc, aluminum and/or magnesium and/or alloys of these metals with one another or with other alloy ingredients. Said process encompasses the cleaning, passivating, and coating of the surfaces. For passivating, an aqueous solution is used which, in addition to complex fluorides of Ti, Zr, Hf, Si and/or B, contains organic polymers. The organic polymers used are preferably poly-4-vinylphenol compounds. These polyvinyl compounds are obtainable preferably by condensing a polyvinylphenol with formaldehyde or paraformaldehyde and a secondary organic amine.

In view of the importance and breadth of use of corrosion inhibitors and protective films for metal surfaces there is a great demand for protective films and corrosion inhibitors whose spectrum of properties, such as adhesion to the metal surface, inhibiting activity, and hydrophobic character, satisfies the stringent requirements with which the treated metal surfaces are required to comply. Moreover, the components of the protective films and/or corrosion inhibitors ought to be easy to obtain in satisfactory quantities and ought to be as inexpensive as possible.

It is an object of the present invention to provide compositions for the surface treatment of metals resulting in at least one of the following improvements to the metal surface: improved corrosion protection, improved adhesion for subsequent enhancement coats (e.g., surface coating or metal deposition), passivation, and a smoother surface (in connection with burnishing, pickling, electropolishing). It is a further object of the present invention to provide processes for the surface treatment of metals and of polymers suitable as components for the compositions of the invention and satisfying the abovementioned requirements. Furthermore, it is an object of the present invention to provide additives for the deposition of metals. A further object is to provide compositions and processes for depositing metals or metal alloys on plastics surfaces.

We have found that these objects are achieved by means of a composition for the treatment of metal surfaces, comprising:
a) at least one polymer as component A, composed of
   aa) at least one amino-containing polymer as component Aa;
   ab) at least one aromatic compound as component Ab, being a phenol or quinone or containing a phenolic or quinonoid structural unit;
   ac) if desired, an aldehyde as component Ac;
b) water or another solvent suitable for dissolving, dispersing, suspending or emulsifying the polymer (component A), as component B;
c) if desired, surface-active compounds, dispersants, suspension media and/or emulsifiers as component C.

This composition of the invention may be used in all processes for metal treatment, especially those where corrosion of a metal surface may occur. Examples of such processes are the passivation, especially phosphating, of metal surfaces, preferably chromium-free, the pickling of metal surfaces, the sealing of metal surfaces, and the deposition of metal on metal surfaces, by nickeling, zincking, tinning, coppering or depositing alloy, for example. Furthermore, the compositions may be used for producing surface coating materials or rust converters. In the processes mentioned, particularly in connection with the passivation of metal surfaces and the deposition of metals on metal surfaces, the compositions comprising the inventively used polymer (component A) bring about an effective inhibiting action and effective adhesion of protective films and/or of an enhancement coat applied over it (e.g., a surface coat or chemically or electrochemically deposited metal coats) to the metal surface. In addition, the compositions of the invention may be used for depositing metals on plastics surfaces, in the manufacture of printed circuit boards, for example.

The compositions of the invention preferably comprise corrosion inhibitor compositions which are used in processes for the surface treatment of metals where corrosion of the metal surface may occur or which are intended to prevent corrosion.

Suitable metal surfaces are, in general, common industrial materials selected from the group consisting of aluminum alloys, magnesium alloys, steel, copper, zinc, tin, nickel, chromium, and common industrial alloys of these metals. Further suitable metal surfaces are precious metals, especially gold and silver and their alloys. Also suitable in general are common industrial metal coatings which may be produced chemically or electro-chemically, selected from the group consisting of zinc and its alloys, preferably metallic zinc, zinc/iron, zinc/nickel, zinc/manganese or zinc/cobalt alloys, tin and its alloys, preferably metallic tin, alloys of tin containing Cu, Sb, Pb, Ag, Bi, and Zn, with particular preference those used as solders, in the manufacture and processing of printed circuit boards, for example, and copper, preferably in the form in which it is used on printed circuit boards and metallized plastics parts.

Where the compositions of the invention are used for the pickling or passivating, especially phosphating, of metal surfaces, the metal surfaces in question are preferably of steel, cast iron, zinc, aluminum, magnesium and/or alloys of these metals with one another or with other alloy ingredients. Particular preference is given in such cases to zinc and aluminum and to alloys of these metals with other alloy ingredients.

Where the compositions of the invention are used for the deposition of metals on metal surfaces, then preference is given to steel surfaces when zincking and depositing zinc alloys and also when coppering and nickeling, and to copper and steel when tinning (including Sn alloys).

It is possible to use the composition of the invention for treating metal surfaces which have not been pretreated. Preferably, however, the metal surfaces have at least been cleaned prior to treatment with the composition of the invention. This cleaning preferably includes, among other operations, an operation of degreasing the metal surface. Suitable cleaning and degreasing processes are known to the skilled worker. It is also possible to use the composition of the invention in a process step following a picking operation or passivating operation on the metal surface; for example, in a surface coating step. The compositions of the invention may also be used as cleaning, pickling, and polishing formulations which comprise additives known to the skilled worker and can be used in corresponding processes.

The compositions of the invention may also be used for the deposition of metals or metal alloys on plastics surfaces. The present specification accordingly further provides compositions for the deposition of metals on plastics surfaces, comprising:
a) at least one polymer as component A, composed of
   aa) at least one amino-containing polymer as component Aa;
   ab) at least one aromatic compound as component Ab, being a phenol or quinone or containing a phenolic or quinonoid structural unit;
   ac) if desired, an aldehyde as component Ac;
b) water or another solvent suitable for dissolving, dispersing, suspending or emulsifying the polymer (component A), as component B;
c) if desired, surface-active compounds, dispersants, suspension media and/or emulsifiers as component C.

Preference is given to compositions which are suitable for nickeling and coppering plastics surfaces; for example, for coppering in the manufacture of printed circuit boards. The plastics surfaces are prepared for the metallizing operation using common industrial processes. The compositions of the invention serve for metallizing the plastic, but may also be employed, where appropriate, in the context of the pretreatment for the metallizing operation.

For the purposes of the present specification, the term “composition” is used to refer both to the ready-to-use compositions and to concentrates. The concentrations specified hereinbelow for the individual components refer to the ready-to-use compositions. The skilled worker is nevertheless aware that, in concentrates, the concentrations of the individual components are, correspondingly, higher.

Component A

Component A is a polymer composed of at least one amino-containing polymer as component Aa and at least one aromatic compound as component Ab which is a phenol or quinone or comprises a phenolic or quinonoid structural unit. If desired, the polymer comprises as component Ac a building block originating from a reaction with an aldehyde.

The term “polymers” should be understood in general to refer to compounds which contain at least three repeating units, preferably more than 10 repeating units. The weight average of the molecular weight of the inventively used polymers is in general from 500 to 5 000 000 g/mol, preferably from 1000 to 1 500 000 g/mol. The polymer may also be in crosslinked form, with the consequence that no molecular weight can be specified although the polymer can be dispersed, emulsified or suspended in common industrial solvents.

Component Aa

Component Aa is an amino-containing polymer. Polymers used with preference include polyethyleneimine, polyvinylamine, poly(vinylformamide-co-vinylamine), polylysine, and polyaminostyrene. Also suitable are polyamine derivatives which still contain amino groups, examples being the reaction products of polyamines with carboxylic acids and/or sulfonic acids, or carboxymethylation products of polyamines. Further suitable and particularly preferred polymers are amino-containing derivatives of polycarboxylates, especially the reaction products of diamines and copolymers containing repeating. maleic, acrylic or methacrylic acid units, such as the reaction products of styrene-maleic anhydride copolymers with diamines. Very particular preference is given to polymers of the formulae (I) and (II):

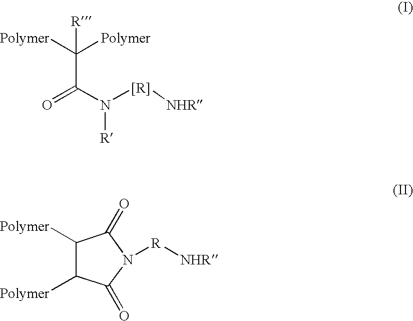

In these formulae, R is an organic radical, preferably an alkylene, cycloalkylene, arylene, arylalkylene or alkylarylene radical. This radical may be interrupted by heteroatorns or substituted as desired, suitable substituents being alkyl, alkenyl, aryl, alkylaryl or arylalkyl radicals, which may in turn be interrupted by heteroatoms or substituted by groups containing heteroatoms. Preferably, R is a C₂₋₃₂-alkylene radical; with particular preference, it is a C₂₋₁₄-alkylene radical which may be interrupted by heteroatoms selected from —N— and —O— and may carry C₁₋₆-alkyl radicals or groups containing heteroatoms, examples being amino groups. Particularly preferred radicals are ethyl, n-butyl, and n-hexyl radicals.

R′, R″ and R′″ independently of one another denote hydrogen or any desired organic radicals. Suitable organic radicals are generally alkyl, cycloalkyl, alkenyl, aryl, alkylaryl, and arylalkyl radicals which may, where appropriate, be interrupted by heteroatoms and/or substituted by groups containing heteroatoms. Preferably, R′, R″ and R′″ independently of one another denote hydrogen or hydrocarbon, with particular preference hydrogen, C₁₋₆ alkyl, C₆₋₁₀ aryl, with very particular preference methyl, ethyl, isopropyl, n-propyl or phenyl.

The amino-containing polymers are available commercially (polyethyleneimine, polyvinyl-amine) or may be prepared by methods which are known to the skilled worker. Suitable processes for preparing polyvinylamine are disclosed, for example, in EP-A 216 387, DE-A 38 42 820, DE-A 195 266 26, DE-A 195 159 43. The polymers of the formulae (I) and (II) used with particular preference are preparable, for example, in accordance with the process disclosed in U.S. Pat. No. 4,046,748.

It is also possible to use the polymer in a mixture with low molecular weight amines. Suitable low molecular weight amines in this case are selected from the group consisting of ethylenediamine, H₂N(—C₂H₄—NH)ₙ—H where n=2-4, and H₂N(—CH₂)ₙ—H where n=1-18, preferably n=2, 3, 4, 6, 8, 10 or 12.

The amino-containing polymers are generally in desalted form. In the case of copolymers containing repeating vinylamine and vinylformamide units, the degree of hydrolysis is generally from 0.5 to 100%, preferably from 50 to 100%.

Component Ab

Component Ab is a phenol or quinone or a compound which comprises a phenolic or quinonoid structural unit.

Suitable quinones or quinone derivatives are generally systems derived from o-benzoquinone or from p-benzoquinone. Preference is given to using systems derived from p-benzoquinone. Particularly preferred compounds are those of the formula (III): 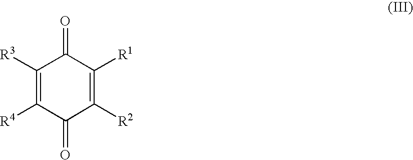
in which R¹, R², R³ and R⁴ independently of one another may be hydrogen or alkyl, alkenyl, cycloalkyl, aryl, alkylaryl or arylalkyl radicals. Preferably, R¹ to R⁴ independently of one another are hydrogen or C₁ to C₁₄ alkyl radicals, C₂ to C₁₄ alkenyl radicals, C₆ to C₁₄ aryl radicals or C₅ to C₁₆ cycloalkyl radicals. It is also possible for R¹ and R² and/or R³ and R⁴ in pairs to form a cyclic radical which may be saturated or unsaturated. This cyclic radical is preferably a ring composed of a total of six carbon atoms, with two carbon atoms originating from the parent structure in formula (III). The radicals mentioned may in turn be substituted by alkyl, alkenyl, cycloalkyl, aryl, arylalkyl or alkylaryl radicals and/or interrupted by heteroatoms or substituted by groups containing heteroatoms. With particular preference, the radicals R¹ to R⁴ in formula (III) independently of one another denote hydrogen and methyl. Compounds of the formula (III) used with particular preference are selected from the group consisting of benzoquinone, 2,3,5-trimethyl-benzoquinone, 2,6-dimethylbenzoquinone, naphthoquinone, and anthraquinone.

Suitable phenols or compounds which comprise a phenolic or quinonoid structural unit are compounds of the formula (IV):

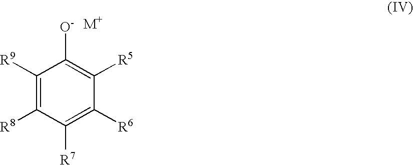

In this formula, the radicals R⁵, R⁶, R⁷, R⁸ and R⁹ independently of one another have the definition specified for R¹ to R⁴. Additionally, the radicals R⁵ and R⁶, R⁶ and R⁷, R⁷ and R⁸, and/or R⁸ and R⁹ may in pairs form a cyclic radical as defined for R¹ and R² and, respectively, R³ and R⁴. Furthermore, one or two of the radicals R⁵ to R⁹ may denote —O⁻M⁺.

M⁺ in formula (IV) denotes hydrogen or a -cation. In general, M⁺ is an alkali metal cation, preferably a sodium or potassium ion. It is, however, also possible for M⁺ to be a cation with a valence of two or more, preferably an alkaline earth metal cation or Zn, Mn or Cr(III), with particular preference magnesium or calcium.

In addition to the abovementioned radicals, R⁵ to R⁹ may also denote —SO₃⁻M⁺, —NO₂, halogen, —COO⁻M⁺, —C(O)R″″ (where R″″ is hydrogen or an alkyl, aryl, cycloalkyl, aralkyl or alkaryl radical), —N(R″″)₂, —OR″″ or —SH or other functional groups which are known to the skilled worker. In general, only one of the radicals R⁵ to R⁹ has one of the last-mentioned definitions.

Preferred compounds of the formula (IV) are 1-, 2- or 3-valent phenols which may be substituted by the radicals mentioned above. In this context, not only the phenolic compounds mentioned but also their salts are suitable.

Particularly preferred compounds of the formula (IV) are phenol, 4,4′-dihydroxydiphenyl sulfide, dihydroxydiphenyl sulfoxide, phenolsulfonic acid, 1,4-dihydroxynaphthalene, nitrophenol, (N,N-dimethylamino)-1-phenol, hydroxythioanisole, pyrogallol, phloro-glucinol, 1,2,4-trihydroxybenzene, 2,2′,4,4′-tetrahydroxybenzophenone, salicylic acid, 2,3-dihydroxybenzoic acid, 2,4-dihydroxybenzoic acid, 2,5-dihydroxybenzoic acid, trihydroxybenzoic acids such as gallic acid, for example, alkyl salicylates such as ethyl salicylate, for example, alkyl 3,4-dihydroxybenzoates such as ethyl 3,4-dihydroxy-benzoates, for example, alkyl gallates such as propyl gallate, for example, 2,3-dihydroxy-benzaldehyde, 2,4-dihydroxybenzaldehyde, 2,5-dihydroxybenzaldehyde, 2,3,4-trihydroxy-benzaldehyde, ((4-tert-butyl-2,6-dimethyl-3-hydroxy)benzyl)imidazoline, (s)-2-(3,4-dihydroxybenzyl)-2-hydrazinopropionic acid, 1,2-dihydroxy-4-tert-butylbenzene, 2-(4-hydroxyphenoxy)propionic acid, 2-(4-hydroxyphenyl)ethylamine, 2-(4-hydroxy-phenyl)ethylamine, 2,3,5-trimethylbenzene-1,4-diol, 2,3-dihydro-1,4-dihydroxyanthra-quinone, 2,4-dichlorophenol, 2,5-dihydroxytoluene, 2,5-dimethylphenol, 2,5-di-tert-pentyl-hydroquinone, 2,7-dihydroxynaphthalene, 2-allylphenol, 2-amino-4,6-dinitrophenol, 2-hydroxy-3-methylbenzoic acid, 2-hydroxyacetophenone, 2-hydroxyanthraquinone, 2-hydroxybenzaldehyde, methyl 2-hydroxybenzoate, 2-hydroxyphenylacetic acid, 2-hydroxyphenyl methylcarbamate, 2-naphthol-3,6-disulfonic acid, 2-tert-butyl-4-methyl-phenol, 2-tert-butylhydroquinone, 3,5-di-tert-butyl-4-hydroxytoluene, 3-aminophenol, 3-carboxy-2-hydroxynaphthalene, 3-methylphenol, 3-tert-butyl-4-hydroxyanisole, 4-(2-(3-(4-hydroxyphenyl)-1-methylpropyl)amino)ethyl)-1,2-dihydroxybenzene, 4,4′-dihydroxy-biphenyl, 4-acetylamino-1-hydroxybenzene, 4-chlorophenol, 4-diazo-3-hydroxy-naphthalene-1-sulfonic acid, 4-hydroxyacetophenone, 4-hydroxybenzoic acid, propyl 4-hydroxybenzoate, 4-hydroxybenzophenone, 4-hydroxymandelic acid, 4-methoxyphenol, 4-methylphenol, 4-nitro-2-aminophenol-6-sulfonic acid, 5-chloro-2-hydroxytoluene, 5-nitro-2-aminophenol, 6-acetylamino-2-amino-1-hydroxybenzene-4-sulfonic acid, 6-hydroxynaphthalene-2-sulfonic acid, 8-hydroxy-2-methylquinoline, 8-hydroxyquinoline, adrenaline, alpha-tocopherol, amylmetacresol, bis(4-hydroxyphenyl) sulfone, bisphenol A, pyrocatechol, dopamine, estradiol, hydroquinone, isatinbiscresol, N,N-bis(hydroxyethyl)-4-hydroxyaniline, N,N-diethyl-m-aminophenol, N,N-dimethyl-2-(4-hydroxyphenyl)-ethylamine sulfate, N,N-dimethyl-4-hydroxyphenylethylamine, N,N′-disalicylalethylene-diamine, octadecyl 3-(3,5-di-tert-butyl-4-hydroxyphenyl)propionate, octylphenol, p-dodecylphenol, and p-isononylphenol. In addition to the phenolic compounds mentioned above, their salts are also suitable.

Particular preference is given to using phenol and pyrocatechol.

Component Ac

The polymer (component A) is composed, if desired, of an aldehyde as further component, component Ac. This further component is present, for example, when the polymer is prepared by Mannich reaction. In general, suitable aldehyde components Ac include all aldehydes. It is preferred to use aldehydes of the formula (V).

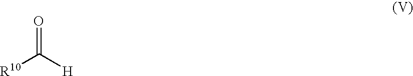

In this formula, R¹⁰ denotes hydrogen, alkyl, alkenyl, cycloalkyl, aryl, aralkyl or alkaryl. It is possible here for the radical R¹⁰ to be substituted by heteroatoms and/or groups which carry heteroatoms. It is also possible for the radicals mentioned for R¹⁰ to be interrupted by heteroatoms. R¹⁰ is preferably hydrogen, C₁₋₁₄ alkyl, C₁₋₁₄ alkenyl, C₅₋₁₆ cycloalkyl, C₆₋₁₄ aryl, C₇₋₁₄ aralkyl or C₇₋₁₈ alkaryl. These radicals may be substituted by radicals containing heteroatoms and selected from the group consisting of halogen, preferably chlorine or bromine, NO₂, SH, OH, acetyl, carboxyl, and —C(O)-phenyl, or interrupted by heteroatoms. The radical R¹⁰ may in turn be substituted itself by alkyl, cycloalkyl, aryl, alkaryl or aralkyl radicals, which in turn may carry groups containing heteroatoms, and/or whose chain and/or ring may be interrupted by heteroatoms.

A particularly preferred component Ac comprises at least one component selected from the group consisting of formaldehyde, ethanal, propanal, butanal, citronellal, benzaldehyde, 2-chlorobenzaldehyde, 2-hydroxybenzaldehyde, 2-propenal, 3,3-dimethylacrolein, 4-methylbenzaldehyde, 4-(1,1-dimethylethyl)benzaldehyde, anisaldehyde, 4-chloro-benzaldehyde, 3-hydroxy-2,2-dimethylpropanal, 7-hydroxy-3,7-dimethyloctanal, N-hexanal, 2-furfural, methyl 3-methyl-4-oxo-2-butenoate, 3-methylbutanal, 2-ethyl-hexanal, 2-methylpropanal, 2-phenylpropionaldehyde, 3,7-dimethylocta-2,6-dien-1-al, 4-(1,1-dimethylethyl)-alpha-methylbenzopropanal, pentanal, 2-methylpentanal, 2-methyl-2-pentenal, 3-acetyloxy-2-methylpropanal, 4-acetoxy-2-methyl-2-butenal, 3-formylpinane, 4-benzyloxybenzaldehyde, 2-methyl-4,4-diacetoxy-2-butenal, 2-methyl-2-propenal, terephthalaldehyde, 3-(4-methylphenyl)-2-methyl-2-propenal, 4-formylbenzoic acid, 3-nitrobenzaldehyde, 3-formyl-4-methyltetrahydropyran, 2-methyl-3-methylthiopropanal, methyl 2-formyl-2-methylpropionate, o-phthalaldehyde, retinal, 3-(4-methoxyphenyl)-2-methyl-2-propenal, 2,3-diphenylpropenaln methyl 3-formyl-2-methylpropionate, and cinnamaldehyde.

The polymers (component A) may be prepared by methods which are known to the skilled worker. Preferred polymers are those obtained by Michael reaction (R1) and those obtained when a suitable aldehyde (component Ac) is added on in a Mannich reaction (P2). The scheme below shows a Michael reaction (R1) involving—as an example—benzoquinone:

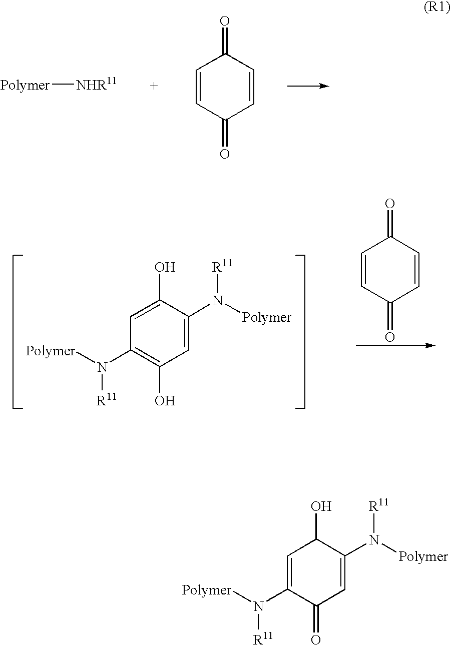

In this scheme, R¹¹ denotes hydrogen or an organic radical, depending on the amino-containing polymer (component Aa) used. Preferably, R¹¹ is hydrogen or methyl.

The Mannich reaction (R2) likewise used with preference for preparing the polymers (component A) is depicted below with the involvement—as an example—of phenol:

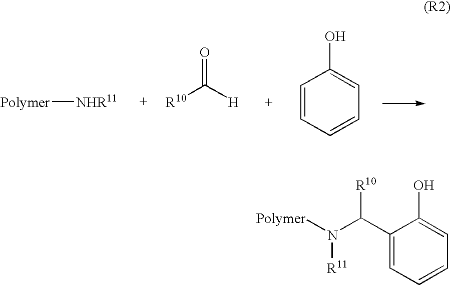

The definitions of R¹⁰ and R¹¹ have already been given above.

In the compositions of the invention, component A is used generally in an amount of from 0.01 to 400 g/l, preferably from 0.2 to 100 g/l, with particular preference from 1 to 50 g/l, based in each case on one liter of the composition. The precise amount of component A is dependent on the respective process for the treatment of metal surfaces and also on the metal surface in question.

Component B

Component B is water or another solvent suitable for dissolving or dispersing, suspending or emulsifying the polymer (component A). Suitable other solvents besides water are, for example, aliphatic or aromatic solvents such as benzene, toluene, and xylene, halogenated solvents such as methylene chloride and chloroform, alcohols such as methanol and ethanol, ethers, such as diethyl ether and tetrahydrofuran, polyethers, especially polyethylene glycol, ketones, such as acetone, and mixtures of these solvents with one another and/or with water. It is particularly preferred to use exclusively water as solvent.

The pH is determined by the nature of the application. By way of example, pickling and phosphating baths are generally highly acidic, and electroplating baths basic or acidic depending on the nature of the bath. pH values suitable for the specific applications are known to the skilled worker.

The amount of water or another solvent is a function of whether the composition of the invention is a ready-to-use composition or a concentrate, and also of the respective end use. Basically, the amount is a function of the concentrations of the individual components that are indicated for the ready-to-use composition.

Component C

Where appropriate, the composition of the invention may further comprise surface-active compounds, emulsifiers and/or dispersants. Suitable surface-active compounds are surfactants, which may be cationic, anionic, zwitterionic or nonionic. Examples of suitable surfactants are alkyl and alkenyl alkoxylates of the type R-EOₙ/POₘ in which R are generally linear or branched C₆-C₃₀ alkyl radicals, preferably C₈-C₂₀ alkyl radicals, and EO is an ethylene oxide unit and PO is a propylene oxide unit, the sequential arrangement of EO and PO being arbitrary, and n and m independently of one another being >1 and <100, preferably >3 and <50, examples being Emulan®, Lutensol® and Plurafac® (from BASF), alkylphenol ethoxylates, EO/PO block copolymers (Pluronic®, from BASF), alkyl ether sulfates, and alkylammonium salts, referred to as quats.

The amount of these components in the composition of the invention is generally 0.01-100 g/l, preferably from 0.1 to 20 g/l.

In one preferred embodiment, the composition of the invention is used for the treatment of metal surfaces and comprises further to components A, B and, where appropriate, C:
d) at least one salt, acid or base based on transition metal cations, transition metal oxo anions, fluorometallates or lanthanoids as component D, and/or
e) at least one acid selected from the group consisting of phosphoric acid, sulfuric acid, sulfonic acids, nitric acid, hydrofluoric acid, and hydrochloric acid, as component E, and/or
f) at least one further corrosion inhibitor as component F, and/or
g) compounds of Ce, Ni, Co, V, Fe, Zn, Zr, Ca, Mn, Mo, W, Cr and/or Bi as component G, and/or
h) further auxiliaries and additives as component H.

These compositions are especially suitable for picking or passivating, especially phosphating, or as rust converters for the metal surfaces mentioned in the present specification.

Component D

Suitable components D are salts, acids, and bases based on transition metal cations, transition metal oxo anions, fluorometallates or lanthanoids. Suitable transition metal cations are, in particular, fluorometallates of Ti(IV), Zr(IV), Hf(IV) and/or Si(IV), and a particularly suitable lanthanoid is Ce. Also suitable are tungstates and molybdates.

Compositions in accordance with the present specification which comprise component D are especially suitable either for depositing a corrosion protection coat on a metal surface or for reinforcing the corrosion protection effect of a corrosion coat already deposited on the metal surface. In the compositions of the invention, the inventively used polymers (component A) have an outstanding corrosion protection effect.

The amount of component D—where component D is present in the compositions of the invention—is preferably from 0.02 to 20 g/l.

Component E

In addition to or instead of component D, the compositions of the invention may further comprise at least one acid selected from the group consisting of phosphoric acid, sulfuric acid, sulfonic acids such as methanesulfonic acid, vinylsulfonic acid, allylsulfonic acid, m-nitrobenzenesulfonic acid, naphthalenesulfonic acid, and derivatives thereof, nitric acid, hydrofluoric acid, and hydrochloric acid. The nature of the acid used is dependent on the type of treatment of the metal surface. Accordingly, phosphoric acid is generally used in phosphating baths for phosphating steel surfaces. In this case the composition of the invention is a phosphating solution. A distinction is made here between what are known as “non-film-forming” phosphating solutions, i.e., solutions containing no divalent metals. These non-film-forming phosphating solutions are in the form, for example, of an iron phosphating solution. Where the phosphating solutions do contain ions of divalent metals, e.g. zinc and/or manganese, the phosphating solutions are said to be film-forming. Compositions in accordance with the present specification that comprise nitric acid are particularly suitable for the surface treatment of zinc and its alloys, whereas compositions comprising hydrofluoric acid are particularly suitable for the surface treatment of aluminum and its alloys.

The amount of acid used may vary depending on the field of application. In general, where component E is present in the compositions of the invention, it is used at from 0.2 to 200 g/l, preferably from 2 to 100 g/l.

Component F

In addition to or instead of components D and/or E, the compositions of the invention may comprise at least one further corrosion inhibitor. Suitable corrosion inhibitors are selected from the group consisting of butynediol, benzotriazole, aldehydes, amine carboxylates, aminophenols and nitrophenols, amino alcohols, aminobenzimidazole, aminoimidazolines, aminotriazole, benzimidazolamines, benzothiazoles, benzotriazole derivatives, esters of boric acid with various alkanolamines, such as boric acid diethanolamine ester, for example, carboxylic acids and their esters, quinoline derivatives, dibenzyl sulfoxide, dicarboxylic acids and their esters, diisobutenylsuccinic acid, dithiophosphonic acid, fatty amines and fatty acid amides, guanidine derivatives, urea and its derivatives, laurylpyridinium chloride, maleamides, mercaptobenzimidazole, N-2-ethylhexyl-3-amino-sulfopropionic acid, phosphonium salts, phthalamides, amine- and sodium-neutralized phosphoric esters of alkyl alcohols, and also these phosphoric esters themselves, phosphoric esters of polyalkoxylates, and particularly of polyethylene glycol, polyetheramines, sulfonium salts, sulfonic acids such as methanesulfonic acid, for example, thioethers, thioureas, thiuramide sulfides, cinnamic acid and its derivatives, zinc phosphates and zinc silicates, and zirconium phosphates and zirconium silicates.

As further corrosion inhibitors it is preferred to use butynediol and benzotriazole (especially for the surface treatment of copper).

If used at all in the compositions, the corrosion inhibitors are used in an amount of generally from 0.01 to 50 g/l, preferably from 0.1 to 20 g/l, with particular preference from 1 to 10 g/l.

Component G

In addition to or, where appropriate, instead of the abovementioned components, it is also possible to employ compounds of Ce, Ni, Co, V, Fe, Zn, Zr, Ca, Mn, Mo, W, Cr and/or Bi. In general, the use of component A in accordance with the invention in the compositions results in such good corrosion protection properties that the addition of the abovementioned compounds is unnecessary. Preferably, the compositions of the invention are free from Cr(VI). Where, nevertheless, the aforementioned compounds (component G) are used, it is preferred to use compounds selected from Fe, Zn, Zr and Ca. The amount of these compounds in the compositions of the invention, where they are present at all, is generally from 0.01 to 100 g/l, preferably from 0.1 to 50 g/, with particular preference from 1 to 20 g/l.

Component H

In addition to one or more of the above components D to G, the compositions of the invention may comprise further auxiliaries and additives. Suitable auxiliaries and additives include conductivity pigments or conductive fillers, e.g., iron phosphide, vanadium carbide, titanium nitride, carbon black, graphite, molybdenum disulfide or tin- or antimony-doped barium sulfate, with iron phosphide being preferred. Conductivity pigments or conductive fillers are added -to the compositions of the invention in order to improve the weldability of the metal surfaces to be treated or in order to improve subsequent coating with electrocoat materials. Moreover, silica suspensions may be employed, particularly when the compositions are used for the treatment of surfaces comprising aluminum.

These auxiliaries and/or additives are generally present in a finely divided form; in other words, their mean particle diameters are generally from 0.005 to 5 μm, preferably from 0.05 to 2.5 μm. The amount of the auxiliaries and additives is generally from 0.1 to 50% by weight, preferably from 2 to 35% by weight, based on the overall mass of the compositions of the invention.

The compositions of the invention may further comprise additions for improving the forming characteristics, examples being wax-based derivatives based on natural or synthetic waxes, e.g., waxes based on acrylic acid, polyethylene waxes, polytetrafluoro-ethylene (PTFE) waxes or wax derivatives or paraffins and their oxidation products.

Depending on their area of application, the compositions of the invention may comprise polymer dispersions based on styrene, 4-hydroxystyrene, butadiene, acrylic acid, acrylic esters, acrylamides, acrylates, methacrylic acid, methacrylic esters, methacrylamides, methacrylates, and derivatives of acrylamide. It is also possible for the compositions of the invention to comprise polyurethane dispersions and polyesterurethane dispersions or polyurea dispersions.

Another group of compounds that may be present in the compositions of the invention embraces polyethylene glycols, polypropylene glycols, copolymers of ethylene oxide, and copolymers of propylene oxide.

Where the compositions of the invention are used in powder coating materials, they may further comprise epoxy resins and/or condensation resins of formaldehyde with phenol, urea, melamine, phenolsulfonic acid or naphthalenesulfonic acid.

When the compositions of the invention are employed in rust converters, they may further comprise polyvinylbutyral.

Depending on the precise makeup of the compositions of the invention comprising component A, they may be used in all applications for the treatment of metal surfaces, particularly in those applications where the corrosion of metal surfaces may pose a problem. Examples of such applications are paint stripping, metal pickling, electro-polishing, chemical deburring, chemical and electrochemical metal deposition (particularly of Cu, Ni, Pd, Zn, Co, Mn, Fe, Mg, Sn, Pb, Bi, Ag, Au, and their alloys), conversion coating (especially no-rinse conversion coating, i.e., processes with a reduced number of rinsing operations, on zincked steel and aluminum, for example), corrosion protection (especially on copper, in printed circuit board manufacture for instance, and on steel) and lubricating and greasing (especially in connection with cold forming). The manner of application is in accordance with common industry methods, with the additional observations that the compositions of the invention are used in unison with further components common in industry for the application in question or that they are brought into contact with the metal in additional treatment steps, such as spraying, dipping, surface coating or electrocoating, for example, using appropriate formulations of the corrosion inhibitor compositions of the invention such as solutions, emulsions, dispersions, suspensions or aerosols.

The present specification further provides compositions for metal deposition, comprising—in addition to components A, B, and, where appropriate, C—
i) at least one metal oxide and/or metal salt as component I,
j) where appropriate, at least one complexing agent as component J,
k) where appropriate, at least one acid or an alkali metal salt or alkaline earth metal salt of the corresponding acid, as component K, and
l) where appropriate, further additions as component L.

These compositions of the invention are particularly suitable for the deposition of metals or metal alloys on metal or plastics surfaces. Suitable metal surfaces have already been specified above. The deposition of metals or metal alloys on plastics surfaces takes place preferably in the context of the manufacture of printed circuit boards. Deposition is preferably carried out in a chemical or electrochemical process.

Component I

Suitable metal oxides or metal salts are the oxides or salts of metals selected from the group consisting of Zn, Ni, Cu, Au, Pd, Sn, Co, Mn, Fe, Mg, Pb, Bi and Ag. The metals may be deposited in the form of the metal used or—when using different metals—in the form of alloys of said metals with one another or with other metals. Preferred alloys are CuZn, CuSn, CuNi, SnPb, SnAgBiCu, SnAgCu, SnBi, SnAg, SnCu, NiPd, NiP, ZnFe, ZnNi, ZnCo, and ZnMn. The aforementioned ingredients of the alloys may be present in any desired concentrations in the alloy. Particular preference is given to depositing Zn, Cu, and Ni, and also alloys of these metals with other metals or with one another. In the context of the deposition of metals or metal alloys on plastics surfaces, Ni and Cu are particularly preferred. Besides their use as metal oxides, the metals may be used as metal salts selected from the corresponding sulfates, salts with sulfonic acids, chlorides, carbonates, sulfamates, fluoroborates, cyanides, and acetates.

The concentration of the metal ions in the compositions of the invention is generally from 0.01 to 100 g/l, preferably from 0.1 to 50 g/l, with particular preference from 2 to 20 g/l, based on the amount of the metal used.

Component J

The compositions of the invention may, where appropriate, further comprise a complexing agent. Examples of suitable complexing agents include ethylenediaminetetraacetic acid (EDTA), ethylenediamine (ED), citric acid, and salts of said compounds.

Component K

The compositions of the invention may, where appropriate, further comprise at least one acid or an alkali metal salt or alkaline earth metal salt of the corresponding acid, selected preferably from the group consisting of HNO₃, H₂SO₄, H₃PO₄, formic acid, and acetic acid. The acid is generally used in an amount of from 0.5 to 700 g/l, preferably from 5 to 200 g/l.

Component L

In addition to the abovementioned components, the compositions of the invention may include further additions, which may differ depending on intended applications, metal to be deposited, objective, and process employed. Suitable additions are 1-(2-vinylpyridinium)-2-ethylsulfobetaine, 1,1-dimethyl-2-propynyl-1-amine, 1-pyridinium-2-ethylsulfobetaine, 1-pyridinium-2-hydroxy-3-propylsulfobetaine, 1-pyridinium-3-propylsulfobetaine, 2,2′-di-chlorodiethyl ether, 2,5-dimethyl-3-hexyne-2,5-diol, 2-butyne-1,4-diol, 2-butyne-1,4-diol ethoxylate, 2-butyne-1,4-diol propoxylate, sodium 3-(2-benzothiazolylthio)-1-propane-sulfonate, sodium, 3,3′-dithiobis(1-propanesulfonate), 3-[(aminoiminomethyl)thio]-1-propanesulfonic acid, sodium 3-[(dimethylamino)thioxomethyl]thio-1-propanesulfonate, potassium 3-[ethoxythioxomethyl]thio-1-propanesulfonate, sodium 3-chloro-2-hydroxy-1-propanesulfonate, 3-hexyne-2,5-diol, sodium 3-mercapto-1-propanesulfonate, 4,4-di-hydroxydiphenyl sulfone, 4-methoxybenzaldehyde, aldehydes, alkylphenyl polyethylene oxide sulfopropyl ether potassium salts, alkyl polyethylene oxide sulfopropyl ether potassium salts such as, for example, tridecyl/pentadecyl polyethylene oxide sulfopropyl ether potassium salt, sodium allylsulfonate, amidosulfonic acid, amine- and sodium-neutralized phosphoric esters of alkyl alcohols, amine carboxylates, aminophenols and nitrophenols, amino alcohols, aminobenzimidazole, aminoimidazolines, aminotriazole, methyl benzylacetoacetate, benzylacetone, benzimidazolamines, benzothiazoles, benzotriazole and its derivatives, benzyl pyridine-3-carboxylate, bisphenol A, esters of boric acid with various alkanolamines such as, for example, boric acid diethanol ester, carboxylic acids and their esters, carboxyethylisothiuronium betaine, quinoline derivatives, copolymers of ethylene and acrylic acid, copolymers of imidazole and epichlorohydrin, copolymers of imidazole, morpholine, and epichlorohydrin, copolymers of N,N′-bis[3-(dimethylamino)propyl]urea and 1,1′-oxybis[2-chloroethane], copolymers of n-butyl acrylate, acrylic acid, and styrene, dibenzyl sulfoxide, dicarboxylic acids and their esters, diethylenetriaminepentaacetic acid and salts derived from it, diisobutenylsuccinic acid, disodium ethylenebisdithiocarbamate, dithiophosphonic acid, ethylamidosulfonic acid, ethylenediaminetetraacetic acid and salts derived from it, ethylglycinediacetic acid and salts derived from it, ethylhexanol ethoxylate, fatty amines and fatty acid amides, formaldehyde, glycerol ethoxylate, guanidine derivatives, urea and its derivatives, hydroxyethyliminodiacetic acid and salts derived from it, imidazole, isopropylamidosulfonic acid, isopropylamidosulfonyl chloride, lauryl/myristyltrimethyl-ammonium methosulfate, laurylpyridinium chloride, maleamides, mercaptobenzimidazole, methylamidosulfonic acid, N,N,N′,N′-tetrakis(2-hydroxypropyl)ethylenediamine, N,N-diethyl-2-propyn-1-amine, N,N-diethyl-4-amino-2-butyn-1-ol, N,N-dimethyl-2-propyn-1-amine, N-2-ethylhexyl-3-aminosulfopropionic acid, N-allylpyridinium chloride, sodium salt of sulfated alkylphenol ethoxylates, sodium 2-ethylhexyl sulfate, nicotinic acid, nitrilotriacetic acid and salts derived from it, sodium nitrobenzenesulfonate, N-methallylpyridinium chloride, ortho-chlorobenzaldehyde, phosphonium salts, phthal-amides, picolinic acid, polyetheramines, polyethyleneimines, polyvinylimidazole, propargyl alcohol, propargyl alcohol ethoxylate, propargyl alcohol propoxylate, sodium propynesulfonate, propiolic acid, propylenediaminetetraacetic acid and salts derived from it, pyrrole, quaternized polyvinylimidazole, reaction product of 2-butyne-1,4-diol and epichlorohydrin, reaction product of 2-butyne-1,4-diol and propane sultone, reaction product of saccharin and propane sultone, reaction product of alkyl ethoxylate/propoxylate with propane sultone, reaction product of polyethyleneimine with propane sultone, reaction product of β-naphthol ethoxylate/propoxylate with propane sultone, resorcinol ethoxylate, saccharin, β-naphthol ethoxylate, sodium β-naphthol ethoxylate sulfate, sulfonium salts, sulfonic acids such as methanesulfonic acid, for example, thiodiglycol, thiodiglycol ethoxylate, thioethers, thioureas, thiuramide sulfides, sodium vinylsulfonate, cinnamic acid and its derivatives, zinc phosphates and zinc silicates, zirconium phosphates and zirconium silicates, hypophosphites (e.g., sodium hypophosphite), NaBH₄, dimethylaminoborane, diethylaminoborane, hydrazine, formaldehyde, urotropin, palladium chloride, sodium stannate, HFₓBF₃, polyethylene glycols of molecular weight 100-1 000 000 g/mol, block copolymers of ethylene oxide and propylene oxide, examples being Pluronic grades from BASF Aktiengesellschaft, Ludwigshafen/Rhein, and random copolymers of ethylene oxide and propylene oxide, especially those with molecular weights in the range 100-2000 g/mol.

Using the compositions of the invention in accordance with this embodiment, it is possible in particular to obtain metal depositions by electrochemical or chemical means. Whether chemical or electrochemical deposition is performed depends on the metal, on the metal surface, and on the desired result.

Process for the Treatment of a Metal or Plastics Surface

The present specification further provides a process for the treatment of a metal surface, which involves contacting the metal surface with a polymer (component A) composed of:
aa) at least one amino-containing polymer as component Aa,
ab) at least one aromatic compound as component Ab, being a phenol or quinone or containing a phenolic or quinonoid structural unit, and
ac) if desired, an aldehyde as component Ac.

This polymer and also preferred embodiments of the polymer and suitable preparation processes have already been mentioned above (see component A). Suitable metal surfaces and also preferred embodiments of the metal surfaces have likewise been mentioned above.

Suitable processes include, for example, paint stripping, metal pickling, electropolishing, chemical deburring, chemical and electrochemical metal deposition, conversion coating (especially no-rinse conversion coating), corrosion protection (especially on copper, such as in circuit board manufacture, and on steel), lubricating, and greasing (especially in the case of cold forming).

In the process of the invention, the polymer may be present as a solution, emulsion, suspension or aerosol. With preference, the polymer (component A) is present in one of the abovementioned compositions of the invention.

The nature of application corresponds to common industry methods, with the added note that the polymers (component A) used in accordance with the invention are employed together with further components customary in industry for the corresponding application, or that they are contacted with the metal in additional treatment steps, such as spraying, dipping, surface coating or electrocoating, for example, using suitable formulations of the polymers.

In one preferred embodiment of the process of the invention, a metal surface is contacted with a composition comprising components A, B and, where appropriate, C, or with a composition comprising not only components A, B and, where appropriate, C but also, as further components, components D and/or E and/or F and/or G and/or H. Suitable components B to H have been set out above. In this preferred embodiment of the process of the invention, it is preferred to carry out pickling or passivating, especially phosphating, of the metal surface. Suitable process steps and apparatus for passivating, especially phosphating, or for pickling metal surfaces are known to the skilled worker.

In general, the metal surface treatment, in particular a passivation, with particular preference a phosphating or pickling treatment, is carried out by spraying a composition of the invention onto the metal surface or by immersing the metal surface in a composition of the invention, depending on the number, size and shape of the parts to be treated.

Where phosphating of metal strips is carried out, the compositions of the invention comprising phosphoric acid as component E may be applied by a roll-on or dry-in-place or no-rinse process, with the phosphating composition of the invention being applied to the metal strip and dried without rinsing, a polymer film being formed.

The present specification further provides a process comprising the following steps:
a) where appropriate, cleaning the metal surface to remove oils, fats, and dirt,
b) where appropriate, washing with water,
c) where appropriate, pickling to remove rust or other oxides, in the presence or absence of the polymer (component A) used in accordance with the invention,
d) where appropriate, washing with water,
e) treatment of the metal surface in the presence of the polymer (component A) used in accordance with the invention,
f) where appropriate, washing with water,
g) where appropriate, aftertreatment, in the presence or absence of the polymer (component A) used in accordance with the invention.

The treatment of the metal surface in step e) may be a passivating treatment, in particular phosphating, in accordance with processes known to the skilled worker. A protective coat, film or impregnation is applied to the metal. Where phosphating is carried out in step e), it is possible to aftertreat the metal surface in step g) with passivating additives.

Washing with water takes place between the individual process steps in order to prevent contamination of the solution required for the following step with components of the solution used in the preceding step. It is, however, also possible to carry out the process of the invention as a no-rinse process, i.e., without steps b), d), and f).

The steps of cleaning (step a)) and of treating the metal surface in the presence of the polymer (component A) used in accordance with the invention, preferably of passivating (step e)), may also be performed in one step, i.e., with a formulation comprising not only the customary cleaning agents but also the composition of the invention.

Following process steps a) to g), the metal surface may be provided with a surface coating material. Surface coating takes place likewise in accordance with processes known to the skilled worker.

A further preferred embodiment of the present specification concerns a process for the deposition of metals or metal alloys on a metal surface, the metal surface being contacted with a composition comprising components A, B and, where appropriate, C, or with a composition comprising not only components A, B, and, where appropriate, C but also, as further components, components I, J where appropriate, K where appropriate, and L where appropriate. Suitable components A, B, C, I, J, K, and L have already been mentioned above.

A further embodiment of the present specification concerns a process for the deposition of metals or metal alloys on a plastics surface, the plastics surface being contacted with a polymer (component A) composed of
aa) at least one amino-containing polymer as component Aa,
ab) at least one aromatic compound as component Ab, being a phenol or quinone or containing a phenolic or quinonoid structural unit, and
ac) if desired, an aldehyde as component Ac.

With preference, in the process of the invention, the plastics surface is contacted with a composition comprising components A, B and, where appropriate, C, or with a composition comprising not only components A, B, and, where appropriate, C but also, as further components, components I, J where appropriate, K where appropriate, and L where appropriate. Suitable components A, B, C, I, J, K, and L have already been mentioned above.

Deposition of metals or metal alloys on a plastics surface is generally carried out in the context of plastics metallization, in particular in the production of printed circuit boards.

In one particularly preferred embodiment of the processes of the invention, the deposition of metals or metal alloys on metal or plastics surfaces takes place in each case chemically or electrochemically. Such processes are known to the skilled worker. With particular preference, the process of the invention comprises chemical or electrochemical deposition of gold, of copper or of nickel, chemical deposition of palladium, electrochemical deposition of zinc, and/or electrochemical deposition of tin. Said processes include not only the deposition of the specified metals but also the deposition of their alloys with other elements; particular preference is given here to CuZn, CuSn, CuNi, SnPb, SnAgBiCu, SnAgCu, SnBi, SnAg, SnCu, NiPd, NiP, ZnFe, ZnNi, ZnCo, ZnMn, said constituents of the alloy being present in the alloy in any desired concentration.

The invention also embraces processes where conductive polymers are deposited, which in the widest sense are regarded as metals. One such conductive polymer is polypyrrole.

Further embodiments of the process of the invention include, for example, cleaning, etching, burnishing, and pickling processes, wherein not only-is the component A used in accordance with the invention but also, at the same time, acids, oxidizing agents and corrosion inhibitors, and dissolved metal salts are used, and also processes for the production of printed circuit boards, in which compositions comprising component A may be used not only for metallizing the circuit board, including the vias present therein, but also for the surface treatment of the circuit board. Compositions comprising component A may on the one hand be used in the surface treatment of metals present on the circuit board, with the objective of corrosion protection, for instance, or for improving the solderability, and also in processes where nonconducting surfaces are treated, as part of the metal deposition process, with the compositions comprising component A that are used in accordance with the invention, with the aim, for instance, of plating the through-holes of printed circuit boards.

In addition to the use of the polymer (component A) used in accordance with the invention in the abovementioned processes, especially for pickling or passivating, especially for phosphating, metal surfaces or for depositing metals on metal surfaces or plastics surfaces, it is possible to add the polymers (component A) used in accordance with the invention wherever corrosion protection is desired.

The present specification further provides for the use of polymers (component A) composed of
aa) at least one amino-containing polymer as component Aa,
ab) at least one aromatic compound as component Ab, being a phenol or quinone or containing a phenolic or quinonoid structural unit, and
ac) if desired, an aldehyde as component Ac
   for the treatment of metal. The polymers (component A) are preferably used for the corrosion inhibition of metal surfaces.

Polymers used with preference and also suitable metal surfaces and suitable processes for corrosion inhibition and processes in which said polymers may be used have already been specified above.

A farther preferred utility relates to the use of polymers composed of
aa) at least one amino-containing polymer as component Aa,
ab) at least one aromatic compound as component Ab, being a phenol or quinone or containing a phenolic or quinonoid structural unit, and
ac) if desired, an aldehyde as component Ac
   for the deposition of metals or metal alloys on a plastics surface.

The polymers (component A) used in accordance with the invention comprise polymers obtained by reacting at least one amino-containing polymer with an aromatic compound and, where appropriate, with an aldehyde. Suitable amino-containing polymers are as already mentioned above under component Aa, including polyvinylamine, polyvinyl-formamide, and polylysine, and also copolymers containing vinylamine, vinylformamide, and lysine as repeating units. The reaction products of these amino-containing polymers with an aromatic compound which is a phenol or quinone or contains a phenolic or quinonoid structural unit, especially-with benzoquinone in a Michael reaction (R1), or with phenol or pyrocatechol in the presence of an aldehyde in a Mannich reaction (R2), are not known from the prior art.

The present specification therefore further provides polymers composed of
a) at least one polymer or copolymer composed of at least one repeating unit selected from the group consisting of vinylamine, vinylformamide and lysine, as component A′a,
b) benzoquinone, phenol or pyrocatechol as component A′b, and
c) where appropriate, an aldehyde as component A′c.

Suitable aldehydes have already been listed above under component Ac. Suitable processes for preparing the polymers of the invention have likewise already been set out above.

These polymers are especially suitable for use in the compositions of the invention and in the processes of the invention for the treatment of metal or plastics surfaces, preferably for the treatment of metal surfaces, and for use for the treatment of metal or plastics surfaces, preferably for the corrosion inhibition of metal surfaces.

The examples which follow further illustrate the invention.

### EXAMPLES

### Examples of the Preparation of Component A

### Examples A1-A3

To N1 parts of an aqueous polyvinylamine solution (polymer in deionized form dissolved 11.15% in water, K value)* of the polymer: 36; prepared by hydrolysis of polyvinyl-formamide, degree of hydrolysis: 96.2%, corresponding to 243.5 mmol of amine per 100 g of polymer) there are added N2 parts of pyrocatechol and subsequently N3 parts of 37% strength aqueous formaldehyde solution. The reaction mixture is heated at 60° C. for 1 hour and after cooling is used as component A.

)* The K value is the Fikentscher constant for characterizing the average molecular weight; cf. H.-G. Elias, Makromoleküle vol. 1, 5th edition, Hüthig & Wepf Verlag, Basel 1990, page 99.

| Fraction | Example A1 | Example A2 | Example A3 |
|---|---|---|---|
| N1 | 208.3 g | 188.3 g | 282.5 g |
| N2 | 0.55 g | 0.022 g | 0.003 g |
| N3 | 0.41 g | 0.016 g | 0.002 g |

### Example A4

0.275 g of pyrocatechol is added to a solution of 32 g of polylysine in 62.7 g of water. The reaction mixture is heated to 60-70° C, and 0.203 g of aqueous formaldehyde solution (37% by weight) is added. After cooling, the reaction product is used as component A.

### Example A5

0.081 g of p-benzoquinone is introduced with cooling into a mixture of 50 g of polyethyleneimine (Lupasol PR 8515 from BASF Aktiengesellschaft, Ludwigshafen am Rhein) and 100 g of water. The reaction product is used as component A.

### Examples A6-A9

0.083 g of pyrocatechol is introduced with cooling into a mixture of N4 parts of polymer and 100 g of water. At room temperature, 0.203 g of aqueous formaldehyde solution (37% by weight) is added and the mixture is then heated to 60-70° C. After cooling, the reaction product is used as component A.

| | Example A6 | Example A7 | Example A8 | Example A9 |
|---|---|---|---|---|
| N4 | 150 g of polyethyleneimine | 154 g of | Mixture of 100 g of | Mixture of 546 g |
| | (Lupasol PR | polyvinylamine | poly(vinylamine- | of polylysine and |
| | 8515 from BASF | | co-vinylformamide) | 150 g of water |
| | Aktiengesellschaft, | | and 20 g of polyvinyl- | |
| | Ludwigshafen am | | formamide | |
| | Rhein) | | | |

### Examples of Processes of the Invention

### Examples B1-B4

Steel panels coated electrolytically with zinc are treated with the following formulations by immersion at 50° C. for 60 seconds:

| | Example | Example | Example | Example |
|---|---|---|---|---|
| | B1 | B2 | B3 | B4 |
| Reaction product | 60 | 60 | | |
| from example A1 | | | | |
| Reaction product | | | 50 | |
| from example A2 | | | | |
| Reaction product | | | | 40 |
| from example A6 | | | | |
| MgCl₂ | 8.5 | | | |
| Na acetate | 45 | 8.5 | | |
| Na formate | 80 | 64 | | |
| 65% nitric acid | | 40 ml/l | | |
| H₂SO₄ | | | 5.5 | |
| H₃PO₄ | | | 16 | |
| NaNO₃ | | | | 50 |
| Formic acid | | | | 75 |
| Acetic acid | | | | 16 |

The numbers in the table denote the concentrations of the respective substances in water in g/l, unless indicated otherwise.

### Examples B5-B8

The same as B1-B4 but using steel panels coated electrolytically with ZnFe (10% by weight Fe content).

### Example B9

Sheet aluminum is anodized at a current density of 15 A/dm² and 100° C. in a solution with the following composition:
H₃PO₄ 70% by weight, H₂SO₄ 10% by weight, HNO₃ 4% by weight, boric acid 0.5% by weight, NH₅F₂ 16% by weight, reaction product from example (A2) 9.5% by weight.

### Example B10

Cast iron is immersed for 15 seconds at room temperature in a solution of 10% of H₂SO₄ and 30% by weight of the reaction product from example A5.

### Example B 11

100 g of a polymer dispersion (30% solids content, composed of a copolymer with the composition 47% by weight n-butyl acrylate, 50% by weight styrene, 3% by weight acrylic acid) are mixed with 100 g of water and 2 g of the reaction product from example A1 and used for coating a zincked steel panel passivated with HNO₃ (0.05% by weight).

### Example B12

### Electrochemical Deposition of Zinc Alloy

For the electrochemical deposition of an alloy coat comprising zinc and a further metal M at 40° C. and a current density of 1.5 A/dm², electroplating baths with the following composition are used.

| | |
|---|---|
| 10 g/l | zinc, as zinc oxide |
| 2 g/l | metal M, as sulfate |
| 100 g/l | sodium hydroxide |
| 15 g/l | carboxymethylated polyethyleneimine, Na salt, from example 1 |
| 5 g/l | polyethyleneimine Lugalvan ® G20 from BASF |
| | Aktiengesellschaft, Ludwigshafen/Rhein |
| 5 g/l | reaction product from example A3 |
| 1 g/l | pyridinium propylsulfobetaine |

The metal M is optionally cobalt, iron, nickel or manganese.

Performance tests B1-B12

The products of examples B1 to B 11 are salt spray tested and have durability times which are 5-30% higher than in the case of comparable processes in which the polymers C are not employed.

Platelet Test

1 g of each of compounds Al to A9 are introduced into 99 g of 0.04 molar aqueous NaCl solution. Steel (1.0037) platelets of known mass are placed in the solution and kept therein for 7 days. The platelets are then freed from adhering rust, rinsed, dried and weighed. The inhibition efficiency of the substances A1 to A9 is calculated from the mass loss Δmₛₐₘₚₗₑ on storage relative to the mass loss on storage without inhibitor, Δm₀, as follows:
E=(Δm₀−Δm_{Probe})/Δm₀

For compounds A1 to A9, E is 5-50%.

Phosphating Test

Each of the substances Al to A9 is used as test substance in the following test:
phosphating solution A: 25 g of phosphoric acid (85%), 10 g of Na acetate, 5 g of test substance, 960 g of water
phosphating solution B: 25 g of phosphoric acid (85%), 10 g of Na acetate, 15 g of test substance, 950 g of water
phosphating solution C: 25 g of phosphoric acid (85%), 10 g of Na acetate, 45 g of test substance, 920 g water phosphating solution D (comparative experiment): 25 g of phosphoric acid (85%), 10 g of Na acetate, 965 g of water

In each case 7 steel panels are treated as follows: (1) clean steel panel//(2) rinse under running water (20 seconds)//(3) immerse in phosphating solution at 90° C.//(4) rinse under running water (20 seconds)//(5) blow dry//(6) store in air (23° C., 50% humidity) for 1 week.
Panel 1: 1 minute in solution A
Panel 2: 25 minutes in solution A
Panel 3: 5 minutes in solution B
Panel 4: 1 minute in solution C
Panel 5: 25 minutes in solution C
Panel 6: 1 minute in solution D
Panel 7: 25 minutes in solution D

For all substances A1 to A9, the panels 1-5 exhibit significantly less rust than panels 6 and 7.

1-12. (canceled)

13. A composition for the treatment of metal surfaces or for the deposition of metal or metal alloys on plastics surfaces, comprising
b) water or another solvent suitable for dissolving, dispersing, suspending or emulsifying the polymer (component A), as component B;
c) if desired, surface-active compounds, dispersants, suspension media and/or emulsifiers as component C
wherein the composition comprises
a) at least one polymer as component A, composed by reaction of
aa) at least one amino-containing polymer as component Aa;
ab) at least one aromatic compound as component Ab, being a phenol or quinone or containing a phenolic or quinonoid structural unit;
ac) if desired, an aldehyde as component Ac.

14. A composition as claimed in claim 13, for the treatment of metal surfaces comprising further to components A, B and, where appropriate, C
d) at least one salt, acid or base based on transition metal cations, transition metal oxo anions, fluorometallates or lanthanoids as component D,
and/or
e) at least one acid selected from the group consisting of phosphoric acid, sulfuric acid, sulfonic acids, nitric acid, hydrofluoric acid, and hydrochloric acid, as component E.

15. Composition as claimed in claim 14, comprising
f) at least one further corrosion inhibitor as component F, and/or
g) compounds of Ce, Ni, Co, V, Fe, Zn, Zr, Ca, Mn, Mo, W, Cr and/or Bi as component G,
and/or
h) further auxiliaries and additives as component H.

16. A composition for the treatment of metal surfaces or for the deposition of metal or metal alloys on plastics surfaces as claimed in claim 13, comprising further to components A, B and, where appropriate, C:
i) at least one metal oxide and/or metal salt as component I,
j) where appropriate, at least one complexing agent as component J.

17. The composition as claimed in claim 16, comprising
k) where appropriate, at least one acid or an alkali metal salt or alkaline earth metal salt of the corresponding acid, as component K, and
l) where appropriate, further additions as component L.

18. A process for the treatment of a metal surface, which comprises contacting the metal surface with a polymer (component A) composed by reaction of
aa) at least one amino-containing polymer as component Aa,
ab) at least one aromatic compound as component Ab, being a phenol or quinone or containing a phenolic or quinonoid structural unit, and
ac) if desired, an aldehyde as component Ac.

19. A process for the treatment of a metal surface, which comprises contacting the metal surface with a composition as claimed in claim 13.

20. A process as claimed in claim 17, comprising the steps of:
a) where appropriate, cleaning the metal surface to remove oils, fats, and dirt,
b) where appropriate, washing with water,
c) where appropriate, pickling to remove rust or other oxides, in the presence or absence of the polymer (component A),
d) where appropriate, washing with water,
e) treatment of the metal surface in the presence of the polymer (component A).

21. A process as claimed in claim 20, additionally comprising the steps of
f) where appropriate, washing with water,
g) where appropriate, aftertreatment, in the presence or absence of the polymer (component A).

22. A composition as claimed in claim 13, wherein the amino-containing polymer is selected from the group consisting of polyethyleneimine, polyvinylamine, poly(vinylformamid-co-vinylamine), polylysine, polyaminostyrene, amino-containing derivatives of polycarboxylates, reaction products of polyamines with carboxylic acids and/or sulfonic acids, and carboxymethylation products of polyamines.
